(19) United States
(12) Patent Application Publication
(10) Pub. No.: US 2024/0262687 A1
(43) Pub. Date: Aug. 8, 2024

(54) GA-BASED VAN DER WAALS ROOM-TEMPERATURE FERROMAGNETIC CRYSTAL MATERIAL, PREPARATION AND USE THEREOF

(71) Applicant: HUAZHONG UNIVERSITY OF SCIENCE AND TECHNOLOGY, Hubei (CN)

(72) Inventors: Haixin CHANG, Hubei (CN); Gaojie ZHANG, Hubei (CN); Hao WU, Hubei (CN)

(73) Assignee: HUAZHONG UNIVERSITY OF SCIENCE AND TECHNOLOGY, Hubei (CN)

(21) Appl. No.: 18/273,780

(22) PCT Filed: Dec. 3, 2022
(86) PCT No.: PCT/CN2022/136400

§ 371 Date: Jul. 24, 2023

(30) Foreign Application Priority Data
Jul. 19, 2022 (CN) 202210849612.2

(51) Int. Cl. C01B 19/00; B82Y 25/00; B82Y 40/00; C30B 9/06; C30B 29/46; H01F 1/147

(52) U.S. Cl. CPC C01B 19/002; C30B 9/06; C30B 29/46; H01F 1/147; B82Y 25/00; B82Y 40/00; C01P 2002/50; C01P 2002/72; C01P 2004/20; C01P 2006/32; C01P 2006/42

(57) ABSTRACT

The present invention provides a Ga-based van der Waals room-temperature ferromagnetic crystal material, preparation and use thereof, which belong to the technical field of nano magnetic material preparation. The materials include Fe₃₋ₐGa_{b}Te₂ (a=−0.3 to 0.1, b=0.8 to 1.2) and Fe_{5-c} GeGa_{d}Te₂ (c=−0.2 to 0.2, d=0.01 to 0.5). The growth method of Fe₃₋ₐGa_{b}Te₂ (a=−0.3 to 0.1, b=0.8 to 1.2) is a self-flux method, using excess Ga and Te as flux to grow crystals. The growth method of Fe_{5-c} GeGa_{d}Te₂ (c=−0.2 to 0.2, d=0.01 to 0.5) uses iodine as a transport agent to grow crystals. The Ga-based van der Waals room-temperature ferromagnetic crystal Fe₃₋ₐ Ga_{b}Te₂ (a=−0.3 to 0.1, b=0.8 to 1.2) and Fe_{5-c}GeGa_{d}Te₂ (c=−0.2 to 0.2, d=0.01 to 0.5) materials have Curie temperature of 330 K to 367 K and 320 K to 345 K, and the saturation magnetic moments are 50 emu/g to 57.2 emu/g and 80 emu/g to 88.5 emu/g, respectively.

### TECHNICAL FIELD

The disclosure belongs to the technical field of nanoscale magnetic material preparation, and more specifically relates to a Ga-based van der Waals room-temperature ferromagnetic crystal material, preparation and use thereof.

### DESCRIPTION OF RELATED ART

Originating from moving charges and spins of elementary particles, magnetism has revolutionized important technologies such as data storage and biomedical imaging, and continues to stimulate new application for emerging materials and reducing dimensions. Although ferromagnetic materials are able to exhibit ferromagnetic order in three-dimensional space, the limitations of the Mermin-Wagner theory hinder the realization of materials with intrinsic ferromagnetism in two-dimensional systems. The theorem points out through a rigorous proof that long-range magnetic order is impossible to exist in a two-dimensional isotropic Heisenberg spin system because thermodynamic fluctuations will destroy all ordered states. Until recently, breakthroughs have been made experimentally in studies of 2D ferromagnetic materials. Just in the past few years, ferromagnetic ordering has been observed in two-dimensional van der Waals crystals with van der Waals structures such as CrI₃, Cr₂Ge₂Te₆, FeₙGeTe₂ (n=3, 4, 5). This series of two-dimensional van der Waals ferromagnetic crystals and their heterostructures not only involve rich physical mechanisms and interesting electronic properties, but also are expected to provide a research platform for a variety of exotic quantum effects, such as quantum anomalous Hall effect, quantum spin Hall effect and Valley Hall effect, etc., and provide a material basis for realization of various multifunctional quantum devices.

However, although the recently discovered two-dimensional van der Waals intrinsic ferromagnetic crystals have promoted the development of intrinsic two-dimensional magnetism and various multifunctional spintronic devices such as tunneling electron magnetic detection, spin quantum sensors, giant tunneling magnetoresistance, spin tunneling field-effect transistors, etc., due to their extremely low Curie temperature, these devices still only operate well below room temperature. Therefore, there is still a considerable level of challenge to prepare an intrinsic two-dimensional van der Waals ferromagnetic crystal with above-room-temperature Curie temperature, large saturation magnetic moment and large perpendicular magnetic anisotropy, and realize two-dimensional quantum device that is able to operate at room temperature based on the intrinsic two-dimensional van der Waals ferromagnetic crystal.

### SUMMARY

The purpose of the present disclosure is to provide a type of Ga-based van der Waals room-temperature ferromagnetic crystal material and a preparation method in order to solve the above problems. By utilizing the present disclosure, it is possible to prepare high-quality Ga-based van der Waals room-temperature ferromagnetic crystal: Fe₃₋ₐGa_{b}Te₂ (a=−0.3˜0.1, b=0.8˜1.2) and Fe_{5-c}GeGa_{d}Te₂ (c=−0.2˜0.2, d=0.01˜0.5). Both Fe₃₋ₐGa_{b}Te₂ (a=−0.3˜0.1, b=0.8˜1.2) and Fe_{5-c}GeGa_{d}Te₂ (c=−0.2˜0.2, d=0.01˜0.5) crystals prepared by the present disclosure have a van der Waals structure, which may be easily exfoliated down to only a few layers. The Curie temperatures are higher than room temperature, respectively 330 K to 367 K and 320 K to 345 K, and the saturation magnetic moments are 50 emu/g to 57.2 emu/g and 80 emu/g to 88.5 emu/g, respectively. Specifically, the perpendicular magnetic anisotropy energy of Fe₃₋ₐGa_{b}Te₂ (a=−0.3˜0.1, b=0.8˜1.2) single crystal may be as high as 3.25×10⁵ to 4.79×10⁵ J/m³. In addition, the thickness of two-dimensional Fe₃₋ₐGa_{b}Te₂ (a=−0.3˜0.1, b=0.8˜1.2) and Fe_{5-c}GeGa_{d}Te₂ (c=−0.2˜0.2, d=0.01˜0.5) nanosheets obtained through mechanical exfoliation is on the order of nanometers, the lateral size is on the order of microns, which is suitable for various current micro-nano processing techniques, and may be adopted to prepare various multifunctional two-dimensional quantum devices. The preparation method of a type of Ga-based van der Waals room-temperature ferromagnetic crystal materials described in the present disclosure has simple process, low cost, and good process stability. This disclosure is expected to facilitate the development and practical application of various multifunctional two-dimensional quantum devices based on Ga-based two-dimensional van der Waals room-temperature ferromagnetic crystals.

According to the first aspect of the present disclosure, a Ga-based van der Waals ferromagnetic crystal material is provided, the ferromagnetic crystal material is Fe₃₋ₐGa_{b}Te₂ ferromagnetic crystal, wherein a=−0.3 to 0.1, b=0.8 to 1.2; or Fe_{5-c}GeGa_{d}Te₂ ferromagnetic crystal, wherein c=−0.2 to 0.2, d=0.01 to 0.5.

Both the Fe₃₋ₐGa_{b}Te₂ compound of the Fe₃₋ₐGa_{b}Te₂ ferromagnetic crystal and the Fe_{5-c}GeGa_{d}Te₂ compound of the Fe_{5-c}GeGa_{d}Te₂ ferromagnetic crystal contain iron atoms with a valence of zero.

The Curie temperatures of the Fe₃₋ₐGa_{b}Te₂ ferromagnetic crystal and the Fe_{5-c}GeGa_{d}Te₂ ferromagnetic crystal are 330 K to 367 K and 320 K to 345 K respectively, and the Fe₃₋ₐGa_{b}Te₂ ferromagnetic crystal and the Fe_{5-c}GeGa_{d}Te₂ ferromagnetic crystal exhibit ferromagnetism below their respective Curie temperatures.

Preferably, the saturation magnetic moments of the Fe₃₋ₐGa_{b}Te₂ ferromagnetic crystal and the Fe_{5-c}GeGa_{d}Te₂ ferromagnetic crystal are 50 emu/g to 57.2 emu/g and 80 emu/g to 88.5 emu/g, respectively.

According to another aspect of the present disclosure, a method for preparing a ferromagnetic crystal is provided, including the following steps.

(1) Mixing Fe powder, Ga block and Te powder thoroughly. The sum of the amount of Fe powder substance and Ga block substance is equal to the amount of Te powder substance; the amount of Fe powder substance accounts for 40% to 60% of the sum of the amount of the Fe powder substance and Ga block substance.

(2) Vacuuming the container containing the mixture obtained in step (1).

(3) Heating the mixture, the heating temperature is 950° C. to 1050° C., and then the temperature is reduced at a rate of 0.5° C./h to 1.5° C./h during the crystal growth process to obtain Fe₃₋ₐGa_{b}Te₂ ferromagnetic crystals, wherein a=−0.3 to 0.1, b=0.8 to 1.2.

Preferably, the heating time is 24 hours to 48 hours.

Preferably, first the temperature is reduced rapidly to 880° C. at a rate of 70° C./h to 170° C./h, then reduced slowly to 780° C. at a rate of 0.5° C./h to 1.5° C./h, and then cooled naturally.

According to another aspect of the present disclosure, a method for preparing a ferromagnetic crystal is provided, including the following steps.

(1) Mixing Fe powder, Ge powder, Ga block, Te powder and I₂ particles thoroughly, the ratio of the amount of Fe powder substance, the sum of the amount of Ge powder substance and Ga block substance, and the amount of Te powder substance is 4:1:2, the amount of the Ge powder substance accounts for 40% to 60% of the sum of the amount of Ge powder substance and Ga block substance.

(2) Vacuuming the container containing the mixture obtained in step (1).

(3) Placing the part of the container containing the mixture in the high-temperature raw material zone in a dual-temperature zone tube furnace, and placing the part of the container not containing the mixture in the low-temperature crystallization zone in the dual-temperature zone tube furnace. The temperature in the high-temperature raw material zone is 950° C. to 1050° C., and the temperature in the low-temperature crystallization zone is 600° C. to 700° C. The I₂ particles serve as a transport agent, and the mixture is transported to the low-temperature crystallization zone for reaction to obtain Fe_{5-c}GeGa_{d}Te₂ ferromagnetic crystals, wherein c=−0.2 to 0.2, d=0.01 to 0.5.

Preferably, in step (3), the reaction time is 168 hours to 330 hours.

Preferably, the ratio of the mass of the I₂ particles to the volume of the container is 3 mg/cm³ to 9 mg/cm³.

According to another aspect of the present disclosure, a use of the Ga-based van der Waals ferromagnetic crystal material in a two-dimensional quantum device is provided.

Preferably, the two-dimensional quantum device is an anomalous Hall device or an electrically regulated magnetic device.

Generally speaking, compared with the related art, the above technical solution conceived by the present disclosure mainly has the following technical advantages.

(1) In the adopted self-flux method, the Fe₃₋ₐGa_{b}Te₂ (a=−0.3˜0.1, b=0.8˜1.2) bulk single crystal grown by slow cooling near the crystallization temperature has high purity and may be easily exfoliated to obtain few-layer two-dimensional nanosheets. The size is suitable for micro-nano processing techniques such as photolithography, and is suitable for the preparation of various multifunctional two-dimensional quantum devices.

(2) In the adopted chemical vapor transport method, iodine is used as a transport agent, and Fe_{5-c}GeGa_{d}Te₂ (c=−0.2˜0.2, d=0.01˜0.5) single crystal grown in the low-temperature crystallization zone of the quartz ampoule at a constant temperature has high purity, and may be easily exfoliated to obtain few-layer two-dimensional nanosheets. The size is suitable for micro-nano processing techniques such as photolithography, and is suitable for the preparation of various multifunctional two-dimensional quantum devices.

(3) With respect to Fe₃₋ₐGa_{b}Te₂ (a=−0.3˜0.1, b=0.8˜1.2), the ratio of raw materials as described in claims is adopted because sufficiently excess Ga and Te is required as fluxes to melt high melting point Fe, and Ga plays a more critical role, so the relationship between the amount of Fe and Ga in the raw material is further defined. With respect to Fe_{5-c}GeGa_{d}Te₂ (c=−0.2˜0.2, d=0.01˜0.5), the ratio of amount of raw material as described in claims is adopted because the four elements involved in the iodine element transport compound have different efficiency. For example, compared with Ge, Ga is more difficult to be transported, so even if the amount of Ga in the compound Fe_{5-c}GeGa_{d}Te₂ (c=−0.2˜0.2, d=0.01˜0.5) is much smaller than Ge, it is still required to put excess Ga into the raw material.

(4) The Curie temperatures of single crystals of a type of Ga-based van der Waals room-temperature ferromagnetic crystals Fe₃₋ₐGa_{b}Te₂ (a=−0.3˜0.1, b=0.8˜1.2) and Fe_{5-c}GeGa_{d}Te₂ (c=−0.2˜0.2, d=0.01˜0.5) are 330 K to 367 K and 320 K to 345 K, respectively. This above-room-temperature ferromagnetism comes from the zero-valence iron atoms contained in both materials.

Fe₃₋ₐGa_{b}Te₂ (a=−0.3˜0.1, b=0.8˜1.2) compound of Fe₃₋ₐGa_{b}Te₂ (a=−0.3˜0.1, b=0.8˜1.2) ferromagnetic crystal has an iron atom with zero valence, the theoretical Curie temperature of zero valence iron atom (i.e. iron element) is as high as 1043 K. However, in the compound, due to the difference in the crystal structure of Fe₃₋ₐGa_{b}Te₂ (a=−0.3˜0.1, b=0.8˜1.2) and Fe_{5-c}GeGa_{d}Te₂ (c=−0.2˜0.2, d=0.01˜0.5) single crystal and elemental iron, the Curie temperature is decreased but is still higher than 300 K, which is higher than most of the known van der Waals ferromagnetic crystals.

(5) A type of Ga-based van der Waals room-temperature ferromagnetic crystals prepared by the present disclosure all have relatively large saturation magnetic moments. Specifically, the saturation magnetic moment of Fe₃₋ₐGa_{b}Te₂ (a=−0.3˜0.1, b=0.8˜1.2) single crystal is 50 emu/g to 57.2 emu/g, and the saturation magnetic moment of Fe_{5-c}GeGa_{d}Te₂ (c=−0.2˜0.2, d=0.01˜0.5) single crystal is 80 emu/g to 88.5 emu/g, which is higher than most known two-dimensional van der Waals ferromagnetic crystals.

(6) The Ga-based van der Waals room-temperature ferromagnetic crystal Fe₃₋ₐGa_{b}Te₂ (a=−0.3˜0.1, b=0.8˜1.2) prepared in the present disclosure has large perpendicular magnetic anisotropy, and the perpendicular magnetic anisotropy energy is as high as 3.25×10⁵˜4.79×10⁵ J/m³ at 300 K, which is higher than most widely-used ferromagnetic thin film materials.

(7) The size of two-dimensional nanosheets obtained by mechanical exfoliation of Fe₃₋ₐGa_{b}Te₂ (a=−0.3˜0.1, b=0.8˜1.2) and Fe_{5-c}GeGa_{d}Te₂ (c=−0.2˜0.2, d=0.01˜0.5) single crystals is on the order of microns and the thickness is on the order of nanometers, which allows micro-nano processing technology such as lithography to be better performed on materials, makes it possible to realize anomalous Hall devices, electrically regulated magnetic devices, etc., and has broad application prospects in the field of two-dimensional quantum devices.

### BRIEF DESCRIPTION OF THE DRAWINGS

FIG. 1 is an X-ray diffraction spectrum of a Ga-based two-dimensional van der Waals room-temperature ferromagnetic Fe₃GaTe₂ single crystal of Example 1.

FIG. 2 is an X-ray diffraction spectrum of a Ga-based two-dimensional van der Waals room-temperature ferromagnetic Fe₅GeGa_{0.1}Te₂ single crystal in Example 4.

FIG. 3 is an energy spectrum element distribution diagram of Ga-based two-dimensional van der Waals room-temperature ferromagnetic crystal Fe₃GaTe₂ nanosheets in Example 1.

FIG. 4 is an energy spectrum element distribution diagram of Ga-based two-dimensional van der Waals room-temperature ferromagnetic crystal Fe₅GeGa_{0.1}Te₂ nanosheets in Example 4.

FIG. 5 shows a spontaneous magnetization curve, and hysteresis loops under out-of-plane magnetic field at different temperatures of a Ga-based two-dimensional van der Waals room-temperature ferromagnetic Fe₃GaTe₂ single crystal of Example 1.

FIG. 6 shows a spontaneous magnetization curve, and hysteresis loops under out-of-plane magnetic field at different temperatures of a Ga-based two-dimensional van der Waals room-temperature ferromagnetic Fe₅GeGa_{0.1}Te₂ single crystal of Example 4.

FIG. 7 shows an anomalous Hall device and above-room-temperature anomalous Hall effect based on a Ga-based two-dimensional van der Waals room-temperature ferromagnetic crystal Fe₃GaTe₂ nanosheets in Example 1.

FIG. 8 shows an anomalous Hall device and above-room-temperature anomalous Hall effect based on Ga-based two-dimensional van der Waals room-temperature ferromagnetic crystal Fe₅GeGa_{0.1}Te₂ nanosheets in Example 4.

FIG. 9 shows a hysteresis loop under in-plane magnetic field at 300K of a Ga-based two-dimensional van der Waals room-temperature ferromagnetic Fe₃GaTe₂ single crystal in Example 1.

FIG. 10 shows an electrically regulated magnetism curve graph of a Ga-based two-dimensional van der Waals room-temperature ferromagnetic Fe₃GaTe₂ single crystal in Example 4.

### DESCRIPTION OF THE EMBODIMENTS

In order to make the purpose, technical solution and advantages of the present disclosure clearer, the present disclosure will be further described in detail below in conjunction with the accompanying drawings and embodiments. It should be understood that the specific embodiments described here are only used to explain the present disclosure, not to limit the present disclosure. In addition, the technical features involved in the various embodiments of the present disclosure described below can be combined with each other as long as they do not constitute a conflict with each other.

With regard to a type of Ga-based van der Waals room-temperature ferromagnetic crystal material and preparation of the same in the present disclosure, the preparation method of the material is as follows.

With respect to Fe₃₋ₐGa_{b}Te₂ (a=−0.3˜0.1, b=0.8˜1.2):

1) Step 1: Fe powder (99.99%), Ga block (99.999%), and Te powder (99.999%) with a particular molar ratio are put into the bottom of a quartz ampoule. A particular molar ratio refers to that the sum of the amount Fe powder substance and Ga block substance is equal to the amount of Te powder substance; the amount of the Fe powder substance accounts for 40% to 60% of the sum of the amount of Fe powder substance and Ga block substance.

2) Step 2: The ampoule is vacuumized and sealed.

3) Step 3: The ampoule is placed in a muffle furnace. The temperature is raised to a range from 950° C. to 1050° C. within 1 hour to 5 hours and kept warm for 1 day to 2 days, then rapidly cooled down to 880° C. and slowly cooled down to 780° C. at a rate of 0.5° C./h to 1.5° C./h. Then the program ends, and the ampoule is naturally cooled to room temperature with the furnace.

With respect to Fe_{5-c}GeGa_{d}Te₂ (c=−0.2˜0.2, d=0.01˜0.5):

1) Step 1: Fe powder (99.99%), Ge powder (99.999%), Ga block (99.999%), Te powder (99.999%) with a particular molar ratio and I₂ particles (99.99%) with a particular mass are put into the bottom of the quartz ampoule. A particular molar ratio refers to that the ratio of the amount of the Fe powder substance, the sum of the amount of the Ge powder substance and the Ga block substance, and the amount of the Te powder substance is 4:1:2, and the amount of the Ge powder substance accounts for 40% to 60% of the sum of the amount of Ge powder substance and Ga block substance.

2) Step 2: The ampoule is vacuumized and sealed.

3) Step 3: The ampoule bottle is placed in a dual-temperature zone tube furnace, the raw material end is a high-temperature raw material zone, and the other end is a low-temperature crystallization zone. The high-temperature zone and the low-temperature zone are respectively heated to 950° C. to 1050° C. and 600° C. to 700° C. within 1 hour to 5 hours and kept warm for 1 week to 2 weeks and cooled down to room temperature naturally.

In some embodiments, the size of the Ga blocks is 1 mm to 10 mm, and the volume is 0.1 cm³ to 0.5 cm³; the diameter of the I₂ particles is 1 mm to 3 mm, and the ratio of the mass of the I₂ particles to the volume of the container is 3 mg/cm³ to 9 mg/cm³, the powder size of the Fe, Ge, Te is 100 mesh to 300 mesh.

In some embodiments, the vacuum sealing process of the quartz tube is as follows: a mechanical pump is pumped to a vacuum below 1 Pa, then washed with argon gas with a purity of 99.999% for thee times to remove the oxygen from the quartz tube, and finally sealed with oxyhydrogen flame.

In some embodiments, the quartz ampoule for growing Fe₃₋ₐGa_{b}Te₂ (a=−0.3˜0.1, b=0.8˜1.2) has a diameter of 2 cm and a length of 10 cm. The quartz ampoule for growing Fe_{5-c}GeGa_{d}Te₂ (c=−0.2˜0.2, d=0.01˜0.5) has a diameter of 2 cm to 5 cm and a length of 40 cm.

In some embodiments, the crystal material sizes of the Fe₃₋ₐGa_{b}Te₂ (a=−0.3˜0.1, b=0.8˜1.2) and Fe_{5-c}GeGa_{d}Te₂ (c=−0.2˜0.2, d=0.01˜0.5) are 2˜3 “×”1˜2“×”0.1˜0.5 mm and 6“×”4“×”0.1˜0.5 mm.

With regard to a type of Ga-based van der Waals room-temperature ferromagnetic crystal material and preparation method for the same in the present disclosure, the Fe₃₋ₐGa_{b}Te₂ (a=−0.3˜0.1, b=0.8˜1.2) and Fe_{5-c}GeGa_{d}Te₂ (c=−0.2˜0.2, d=0.01˜0.5) crystal materials are all high-quality room-temperature ferromagnetic compounds, which have a van der Waals structure and are easily exfoliated mechanically. The crystal materials are silvery white, and may be exfoliated into flat and thin sheet-like two-dimensional nanocrystals, which may be used to prepare various multifunctional two-dimensional quantum devices; the materials are all single crystals.

A type of Ga-based van der Waals room-temperature ferromagnetic crystal material and preparation method for the same in the present disclosure will now be further described in detail in conjunction with the following specific examples and accompanying drawings.

### Example 1

1) The high-purity Fe powder, Ga block and Te powder were weighted with a molar ratio of 1:1:2, and poured into the bottom of the quartz ampoule respectively and vacuumed for sealing.

2) The sealed ampoule was placed in the muffle furnace. The temperature was raised to 1000° C. within 1 hour and kept warm for 1 day, then quickly cooled down to 880° C. at a rate of 100° C./h and slowly cooled down to 780° C. at a rate of 1° C./h. Then the program was finished, and the ampoule was naturally cooled to room temperature with the furnace to obtain Fe₃GaTe₂ single crystal.

### Example 2

1) The high-purity Fe powder, Ga block and Te powder were weighted with a molar ratio of 0.8:1.2:2, and poured into the bottom of the quartz ampoule respectively and vacuumed for sealing.

2) The sealed ampoule was placed in the muffle furnace. The temperature was raised to 1000° C. within 1 hour and kept warm for 1 day, then quickly cooled down to 880° C. at a rate of 100° C./h and slowly cooled down to 780° C. at a rate of 1° C./h. Then the program was finished, and the ampoule was naturally cooled to room temperature with the furnace to obtain Fe_{2.9}Ga_{1.2}Te₂ single crystal.

### Example 3

1) The high-purity Fe powder, Ga block and Te powder were weighted with a molar ratio of 1.2:0.8:2, and poured into the bottom of the quartz ampoule respectively and vacuumed for sealing.

2) The sealed ampoule was placed in the muffle furnace. The temperature was raised to 1000° C. within 1 hour and kept warm for 1 day, then quickly cooled down to 880° C. at a rate of 100° C./h and slowly cooled down to 780° C. at a rate of 1° C./h. Then the program was finished, and the ampoule was naturally cooled to room temperature with the furnace to obtain Fe_{3.3}Ga_{0.8}Te₂ single crystal.

### Example 4

1) The high-purity Fe powder, Ge powder, Ga block and Te powder were weighted with a molar ratio of 8:1:1:4, the I₂ particles were weighted with a mass of 0.3 g, and poured into the bottom of the quartz ampoule respectively and vacuumed for sealing.

2) The sealed ampoule bottle was placed in a dual-temperature zone tube furnace, the raw material end is a high-temperature raw material zone, and the other end is a low-temperature crystallization zone. The high-temperature zone and the low-temperature zone were respectively heated to 1000° C. and 650° C. within 1 hour and kept warm for 2 weeks and cooled down to room temperature naturally, and Fe₅GeGa_{0.1}Te₂ single crystal was obtained in low-temperature crystallization zone.

### Example 5

1) The high-purity Fe powder, Ge powder, Ga block and Te powder were weighted with a molar ratio of 8:1.2:0.8:4, the I₂ particles were weighted with a mass of 0.3 g, and poured into the bottom of the quartz ampoule respectively and vacuumed for sealing.

2) The sealed ampoule bottle was placed in a dual-temperature zone tube furnace, the raw material end is a high-temperature raw material zone, and the other end is a low-temperature crystallization zone. The high-temperature zone and the low-temperature zone were respectively heated to 1000° C. and 650° C. within 1 hour and kept warm for 2 weeks and cooled down to room temperature naturally, and Fe_{5.2}GeGa_{0.01}Te₂ single crystal was obtained in low-temperature crystallization zone.

### Example 6

1) The high-purity Fe powder, Ge powder, Ga block and Te powder were weighted with a molar ratio of 8:0.8:1.2:4, the I₂ particles were weighted with a mass of 0.3 g, and poured into the bottom of the quartz ampoule respectively and vacuumed for sealing.

2) The sealed ampoule bottle was placed in a dual-temperature zone tube furnace, the raw material end is a high-temperature raw material zone, and the other end is a low-temperature crystallization zone. The high-temperature zone and the low-temperature zone were respectively heated to 1000° C. and 650° C. within 1 hour and kept warm for 2 weeks and cooled down to room temperature naturally, and Fe_{4.8}GeGa_{0.5}Te₂ single crystal was obtained in low-temperature crystallization zone.

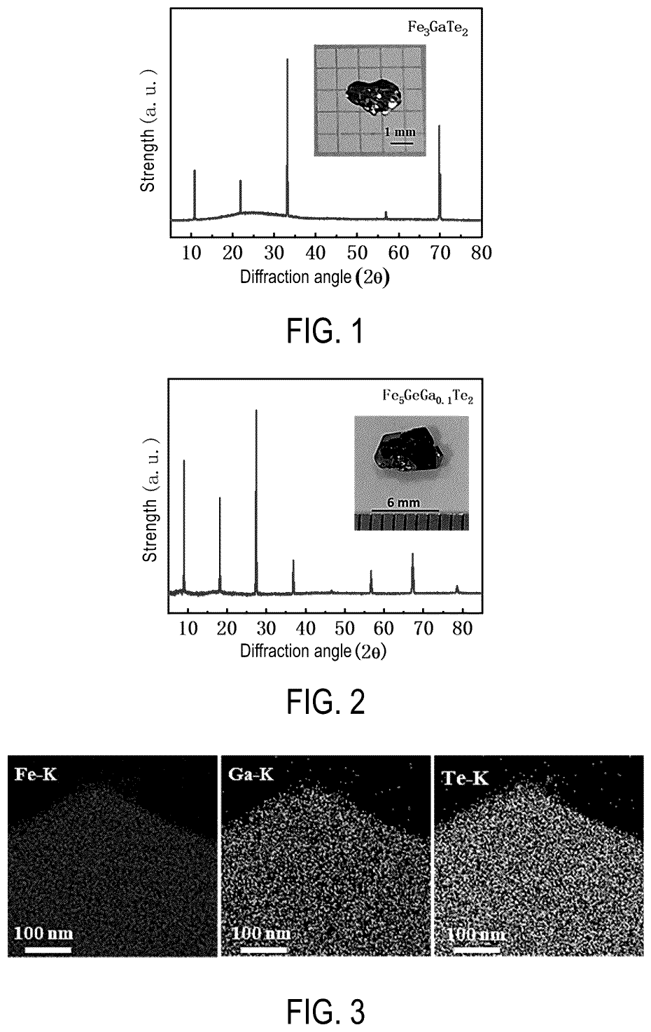

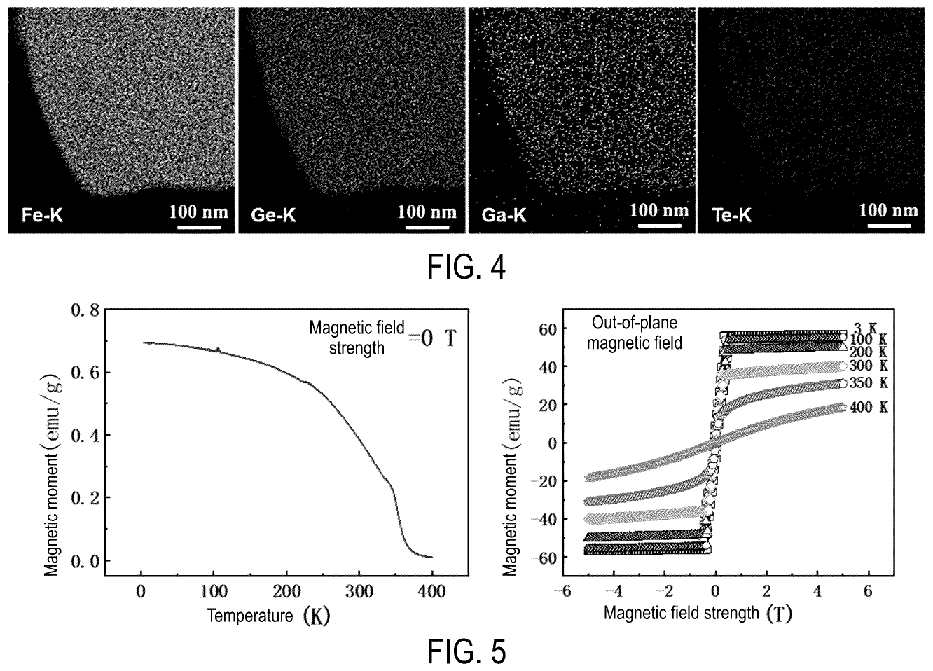

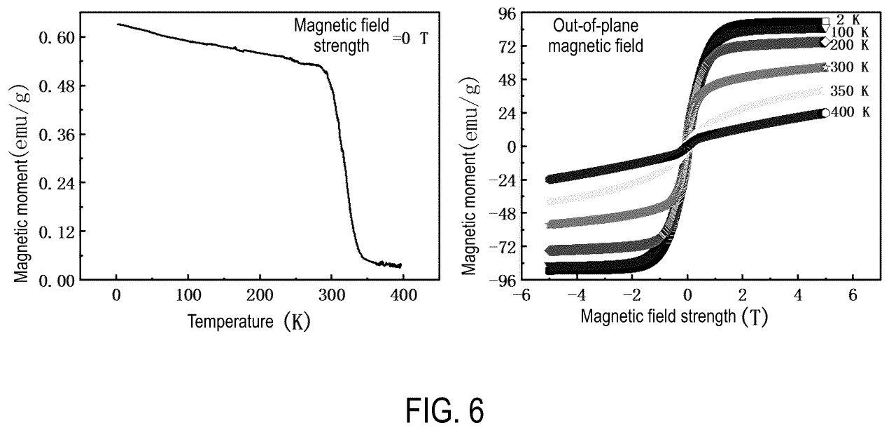

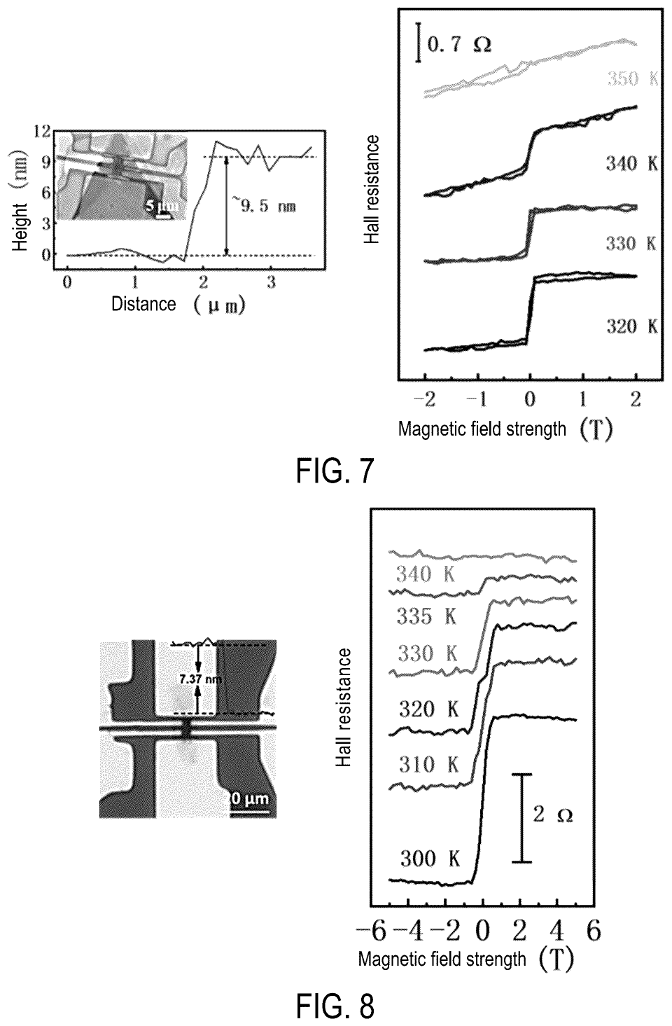

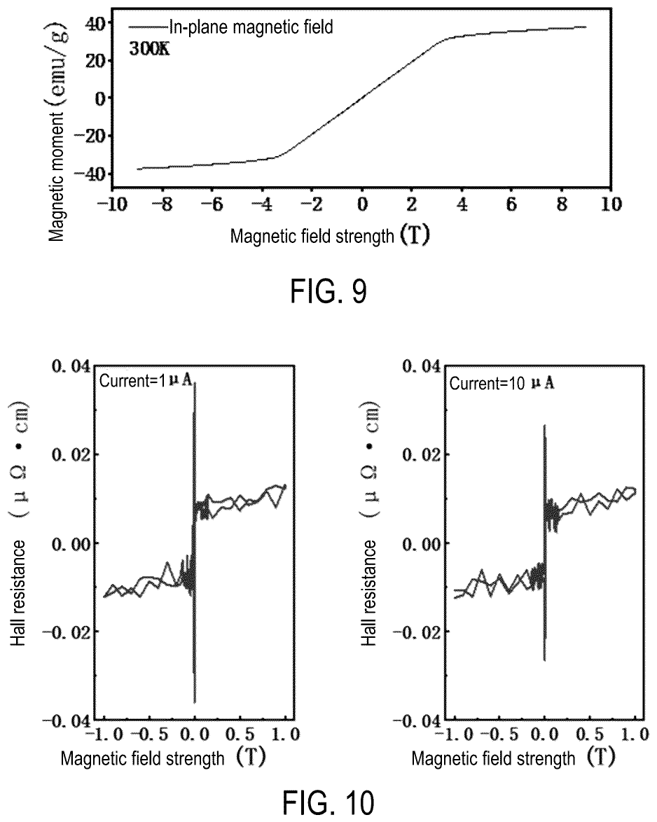

FIG. 1 is an X-ray diffraction spectrum of Fe₃GaTe₂ single crystal. After comparing FIG. 1 with the theoretical X-ray diffraction spectrum, it can be seen that the equidistant diffraction peaks in the X-ray diffraction spectrum of Fe₃GaTe₂ single crystal correspond to the (001) crystal plane, and no impurity peaks are observed, which indicates that the synthesized Fe₃GaTe₂ single crystal has high crystal quality and strict growth orientation. FIG. 2 is an X-ray diffraction spectrum of Fe₅GeGa_{0.1}Te₂ single crystal. After comparing FIG. 2 with the theoretical X-ray diffraction spectrum, it can be seen that the equidistant diffraction peaks in the X-ray diffraction spectrum of Fe₅GeGa_{0.1}Te₂ single crystal correspond to the (001) crystal plane, and no impurity peaks are observed, which indicates that the synthesized Fe₅GeGa_{0.1}Te₂ single crystal has high crystal quality and strict growth orientation. FIG. 3 is an energy spectrum element distribution diagram of Fe₃GaTe₂ nanosheets, and energy spectrum analysis shows that Fe, Ga, and Te elements are evenly distributed in Fe₃GaTe₂. FIG. 4 is an energy spectrum element distribution diagram of Fe₅GeGa_{0.1}Te₂ nanosheets, and energy spectrum analysis shows that the Fe, Ge, Ga, and Te elements are evenly distributed in Fe₅GeGa_{0.1}Te₂. FIG. 5 shows a spontaneous magnetization curve, and hysteresis loops under out-of-plane magnetic field at different temperatures of Fe₃GaTe₂ single crystal, which shows intrinsic above-room-temperature ferromagnetism and large saturation magnetic moment of Fe₃GaTe₂ single crystal. FIG. 6 shows a spontaneous magnetization curve, and hysteresis loops under out-of-plane magnetic field at different temperatures of Fe₅GeGa_{0.1}Te₂ single crystal, which shows intrinsic above-room-temperature ferromagnetism and large saturation magnetic moment of Fe₅GeGa_{0.1}Te₂ single crystal. FIG. 7 shows an anomalous Hall device and above-room-temperature anomalous Hall effect of Fe₃GaTe₂ nanosheets, which shows the easy-exfoliating characteristics of Fe₃GaTe₂ single crystal, intrinsic above-room-temperature ferromagnetism and the application potential of two-dimensional quantum devices. FIG. 8 shows an anomalous Hall device and above-room-temperature anomalous Hall effect of Fe₅GeGa_{0.1}Te₂ nanosheets, which shows the easy-exfoliating characteristics of Fe₅GeGa_{0.1}Te₂ single crystal, intrinsic above-room-temperature ferromagnetism and the application potential of two-dimensional quantum devices. FIG. 9 shows a hysteresis loop under in-plane magnetic field at 300 K of a Ga-based two-dimensional van der Waals room-temperature ferromagnetic Fe₃GaTe₂ single crystal in Example 1. Based on FIG. 9, it can be calculated that the perpendicular magnetic anisotropy energy of Fe₃GaTe₂ at 300 K is as high as 4.79×10⁵ J/m³. FIG. 10 shows an electrically regulated magnetism curve graph of a Ga-based two-dimensional van der Waals room-temperature ferromagnetic Fe₃GaTe₂ single crystal in Example 1. FIG. 10 shows that the current flowing through the device has an obvious adjustment effect on the Hall resistance of the sample, exhibiting an application prospect thereof in the field of two-dimensional quantum devices.

It is easy for those skilled in the art to understand that the above descriptions are only preferred embodiments of the present disclosure, and are not intended to limit the present disclosure. Any modifications, equivalent replacements and improvements made within the spirit and principles of the present disclosure should all be included within the protection scope of the present disclosure.

1. A Ga-based van der Waals ferromagnetic crystal material, wherein the ferromagnetic crystal material is a Fe₃₋ₐ Ga_{b}Te₂ ferromagnetic crystal, wherein a=−0.3 to 0.1, b=0.8 to 1.2; or a Fe_{5-c} Ga_{d}Te₂ ferromagnetic crystal, wherein c=−0.2 to 0.2, d=0.01 to 0.5;
both a Fe₃₋ₐGa_{b}Te₂ compound of the Fe₃₋ₐGa_{b}Te₂ ferromagnetic crystal and a Fe_{5-c} GeGa_{d}Te₂ compound of the Fe_{5-c}GeGa_{d}Te₂ ferromagnetic crystal contain iron atoms with a valence of zero;
Curie temperatures of the Fe₃₋ₐGa_{b}Te₂ ferromagnetic crystal and the Fe_{5-c} GeGa_{d}Te₂ ferromagnetic crystal are 330 K to 367 K and 320 K to 345 K respectively, and the Fe₃₋ₐ Ga_{b}Te₂ ferromagnetic crystal and the Fe_{5-c} GeGa_{d}Te₂ ferromagnetic crystal exhibit ferromagnetism below their respective Curie temperatures.

2. The Ga-based van der Waals ferromagnetic crystal material according to claim 1, wherein saturation magnetic moments of the Fe₃₋ₐ Ga_{b}Te₂ ferromagnetic crystal and the Fe_{5-c} GeGa_{d}Te₂ ferromagnetic crystal are 50 emu/g to 57.2 emu/g and 80 emu/g to 88.5 emu/g, respectively.

3. A method for preparing a ferromagnetic crystal, comprising following steps:
(1) mixing Fe powder, Ga block and Te powder thoroughly, a sum of an amount of the Fe powder and the Ga block is equal to an amount of the Te powder; the amount of the Fe powder accounts for 40% to 60% of the sum of the amount of the Fe powder and the Ga block;
(2) vacuuming a container containing a mixture obtained in step (1); and
(3) heating the mixture, a heating temperature is 950° C. to 1050° C., and then the heating temperature is reduced at a rate of 0.5° C./h to 1.5° C./h during a crystal growth process to obtain a Fe₃₋ₐGa_{b}Te₂ ferromagnetic crystal, wherein a=−0.3 to 0.1, b=0.8 to 1.2.

4. The method for preparing the ferromagnetic crystal according to claim 3, wherein a heating time is 24 hours to 48 hours.

5. The method for preparing the ferromagnetic crystal according to claim 3, wherein first the heating temperature is reduced rapidly to 880° C. at a rate of 70° C./h to 170° C./h, then reduced slowly to 780° C. at a rate of 0.5° C./h to 1.5° C./h, and then cooled naturally.

6. A method for preparing a ferromagnetic crystal, comprising following steps:
(1) mixing Fe powder, Ge powder, Ga block, Te powder and I₂ particles thoroughly, a ratio of an amount of the Fe powder, a sum of an amount of the Ge powder and the Ga block, and an amount of the Te powder is 4:1:2, the amount of the Ge powder accounts for 40% to 60% of the sum of the amount of the Ge powder and the Ga block;
(2) vacuuming a container containing a mixture obtained in step (1); and
(3) placing a part of the container containing the mixture in a high-temperature raw material zone in a dual-temperature zone tube furnace and placing a part of the container not containing the mixture in a low-temperature crystallization zone in the dual-temperature zone tube furnace, a temperature in the high-temperature raw material zone is 950° C. to 1050° C., and a temperature in the low-temperature crystallization zone is 600° C. to 700° C.; the I₂ particles serve as a transport agent; and transporting the mixture to the low-temperature crystallization zone for reaction to obtain a Fe_{5-c} GeGa_{d}Te₂ ferromagnetic crystal, wherein c=−0.2 to 0.2, d=0.01 to 0.5.

7. The method for preparing the ferromagnetic crystal according to claim 6, wherein in step (3), a time of the reaction is 168 hours to 330 hours.

8. The method for preparing the ferromagnetic crystal according to claim 6, wherein a ratio of a mass of the I₂ particles to a volume of the container is 3 mg/cm³ to 9 mg/cm³.

9. A use of the Ga-based van der Waals ferromagnetic crystal material in a two-dimensional quantum device according to claim 1.

10. The use according to claim 9, wherein the two-dimensional quantum device is an anomalous Hall device or an electrically regulated magnetic device.
